(19) United States
(12) Patent Application Publication
(10) Pub. No.: US 2025/0218823 A1
(43) Pub. Date: Jul. 3, 2025

(54) COVER MODULE AND SUBSTRATE TREATMENT APPARATUS INCLUDING COVER MODULE

(71) Applicant: SEMES CO., LTD., Cheonan-si (KR)

(72) Inventors: Sung Gyu LEE, Suwon-si (KR); Ji Young CHOI, Hwaseong-si (KR); Byoung Doo CHOI, Cheonan-si (KR)

(21) Appl. No.: 18/932,470

(22) Filed: Oct. 30, 2024

(30) Foreign Application Priority Data
Dec. 29, 2023 (KR) 10-2023-0195874

(51) Int. Cl. H01L 21/67

(52) U.S. Cl. CPC H01L 21/67196; H01L 21/67017; H01L 21/67167

(57) ABSTRACT

A cover module includes a base portion, a cover portion disposed on an upper portion of the base portion, the cover portion including an upper plate, a first cover disposed at a first end of the upper plate to be openable and closable, and a second cover disposed at a second end of the upper plate to be openable and closable, and a gas supply unit including a first supply portion disposed on the upper plate and a second supply portion disposed on at least one of the first cover and the second cover.

### CROSS-REFERENCE TO RELATED APPLICATION(S)

This application claims benefit of priority to Korean Patent Application No. 10-2023-0195874 filed on Dec. 29, 2023 in the Korean Intellectual Property Office, the disclosure of which is incorporated herein by reference in its entirety.

### BACKGROUND

### 1. Field

The present disclosure relates to a cover module and a substrate treatment apparatus including the same.

### 2. Description of Related Art

In order to manufacture a semiconductor device, a predetermined pattern may need to be formed on a substrate such as a wafer. When a predetermined pattern is formed on a substrate, a deposition process, a lithography process, and an etching process may be continuously performed. Such processes may be performed in respective chambers (units) separated from each other, and a substrate on which a process has been completed in one chamber may be transported to another chamber by a transport unit, and a subsequent process may be performed.

Humidity control may be a key element in metal-oxide resist (MOR)-based chemicals, and humidity control may be performed in a chamber. However, humidity may not be controlled when a substrate is carried out of the chamber for transport. In this regard, MOR-based chemicals may move in a state in which a substrate is disposed on a robot hand of a transport unit while a substrate treatment process is being performed in a facility, and the transport unit may be disposed in an externally exposed state. Accordingly, the substrate may inevitably come into contact with moisture in the facility. When the substrate comes into contact with moisture, OH— of moisture may ultimately affect a CD variation. Thus, it is necessary to develop a technology capable of preventing contact with moisture when transporting a substrate.

### PRIOR ART DOCUMENT

### Patent Document

Patent Document 1: KR Patent Publication No. 10-1033408 (Apr. 28, 2011)

### SUMMARY

An aspect of the present disclosure provides a cover module capable of preventing a substrate from coming into contact with external air and moisture while being transported to a processing chamber, and a substrate treatment apparatus including the same.

According to an aspect of the present disclosure, there is provided a cover module including a base portion, a cover portion disposed on an upper portion of the base portion, the cover portion including an upper plate, a first cover disposed at a first end of the upper plate to be openable and closable, and a second cover disposed at a second end of the upper plate to be openable and closable, and a gas supply unit including a first supply portion disposed on the upper plate and a second supply portion disposed on at least one of the first cover and the second cover.

According to another aspect of the present disclosure, there is provided a substrate treatment apparatus including a first processing chamber having a first internal space, a first opening connected to the first internal space, and a first opening/closing portion opening and closing the first opening, a cover module disposed on one side of the first processing chamber, the cover module including a base portion, a cover portion disposed on an upper portion of the base portion, the cover portion including an upper plate, a first cover disposed at a first end of the upper plate to be openable and closable, and a second cover disposed at a second end of the upper plate to be openable and closable, the second cover opposing the first cover in a first direction, and a gas supply unit including a first supply portion disposed on the upper plate and a second supply portion disposed on at least one of the first cover and the second cover.

According to another aspect of the present disclosure, there is provided a substrate treatment apparatus including a first processing chamber having a first internal space, a first opening connected to the first internal space, and a first opening/closing portion opening and closing the first opening, a second processing chamber disposed to be spaced apart from one side of the first processing chamber, a cover module between the first processing chamber and the second processing chamber, the cover module including a base portion having an accommodation space formed to be concave inwardly from an upper surface thereof, a cover portion disposed on an upper portion of the base portion, the cover portion including an upper plate, a first cover disposed at a first end of the upper plate to be rotatable in a first rotation direction, and a second cover disposed at a second end of the upper plate to be rotatable in a second rotation direction, the second cover opposing the first cover in a first direction, and a gas supply unit including a first supply portion disposed on the upper plate and a second supply portion disposed on at least one of the first cover and the second cover, and a transport unit disposed on the base portion, the transport unit being reciprocatable in a length direction of the base portion, between the first processing chamber and second processing chamber. The cover portion may close the upper portion of the base portion to form a transport space using the first cover and the second cover, between the first processing chamber and the second processing chamber, and the first cover may rotate to close one side surface of the transport space such that an outer end of the first cover comes into contact with the base portion, and the second cover may rotate to close the other side surface of the transport space such that an outer end of the second cover comes into contact with the base portion. The first opening/closing portion may descend and be inserted into the accommodation space to allow the first internal space and the transport space to communicate with each other. The first cover and the second cover may start to rotate to close opposite side surfaces of the base portion, when the first opening/closing portion descends.

A cover module and the substrate treatment apparatus including the same according to aspects of the present disclosure may supply nitrogen gas after closing a peripheral portion of a transport unit before a substrate is introduced into a processing chamber, thereby creating a N₂ atmosphere. Accordingly, the substrate may be transported in the N₂ atmosphere while moving between processing chambers, thereby preventing the substrate from coming into contact with external gas and moisture included therein until the substrate is supplied into the processing chamber. As a result, the occurrence of issues, such as damage to a substrate due to contact with moisture and damage to a pattern due to particles included in external gas, may be prevented, thereby minimizing defects in the substrate.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a top view of a substrate treatment apparatus;

FIG. 2 is a view of the substrate treatment apparatus of FIG. 1 in a direction of A-A;

FIG. 3 is a view of the substrate treatment apparatus of FIG. 1 in a direction of B-B;

FIG. 4 is a schematic perspective view of a cover module excluding a cover portion according to an example embodiment of the present disclosure;

FIG. 5 is a perspective view of an open state of a cover module according to an example embodiment of the present disclosure;

FIG. 6 is a cross-sectional view of the cover module of FIG. 5 in a direction of I-I′;

FIG. 7 is a cross-sectional view of a portion of the cover module of FIG. 5 in a direction of II-II′;

FIG. 8 is a perspective view of a closed state of the cover module according to example embodiment of the present disclosure;

FIG. 9 is a cross-sectional view of the cover module of FIG. 8 in a direction of I-I′; and

FIG. 10 is a cross-sectional view of a portion of the cover module of FIG. 8 in a direction of II-II′.

### DETAILED DESCRIPTION

Hereinafter, preferred example embodiments will be described in detail, such that the disclosure could be easily carried out. In describing example embodiments of the present disclosure, when it is determined that a detailed description of a known technology related to the present disclosure may unnecessarily obscure the gist of the present disclosure, a detailed description thereof will be omitted. In addition, the same reference numerals are used throughout the drawings with respect to components having similar functions and actions. In addition, as used herein, the terms such as “upper,” “upper portion,” “upper surface,” “lower,” “lower portion,” “lower surface,” and “side surface” are based on the drawings, may vary depending on a direction in which an element or component is actually arranged.

In addition, it will be understood that “comprises” or “includes” and/or “comprising” or “including” specify the presence of components, but do not preclude the presence or addition of other components.

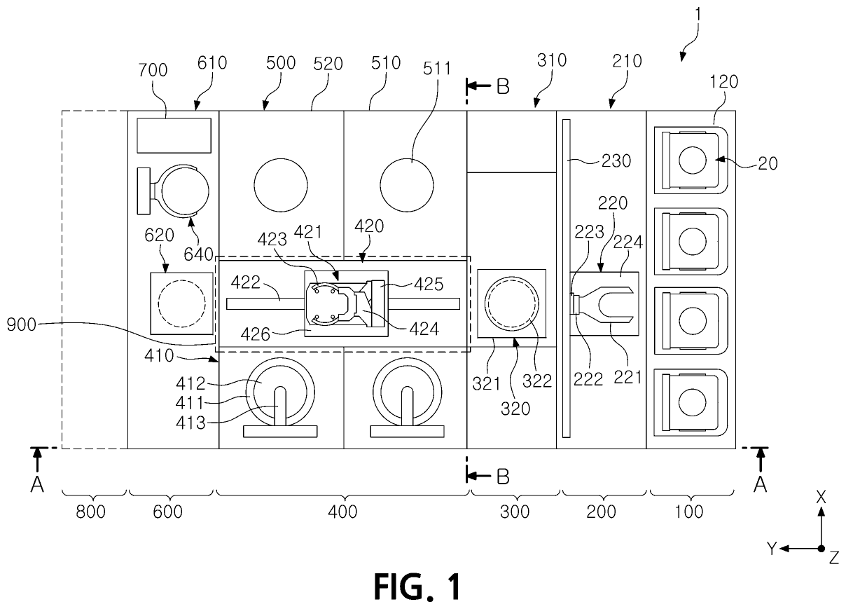

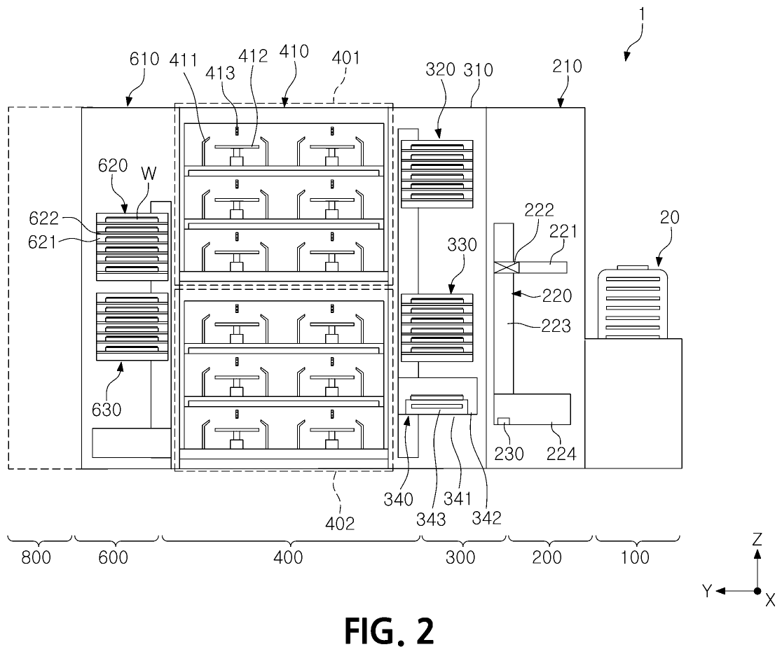

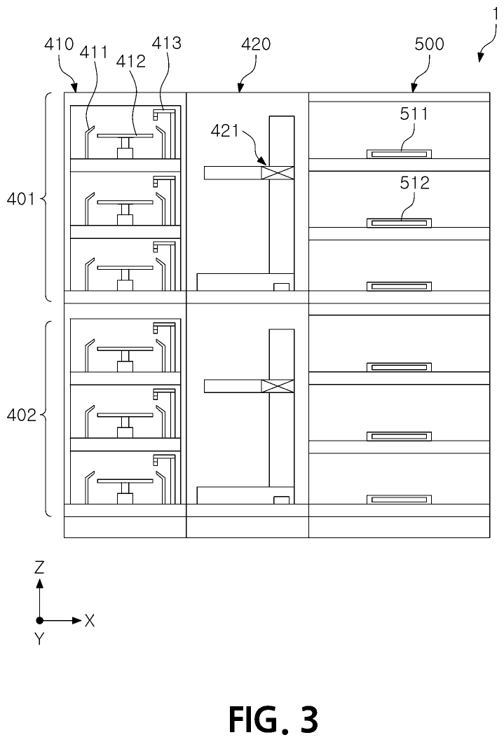

FIG. 1 is a top view of a substrate treatment apparatus, FIG. 2 is a view of the substrate treatment apparatus of FIG. 1 in a direction of A-A, and FIG. 3 is a view of the substrate treatment apparatus of FIG. 1 in a direction of B-B.

Referring to FIGS. 1 to 3, a substrate treatment apparatus 1 may include a load port 100, an index module 200, a buffer module 300, a coating and development module 400, and a purge module 700. The load port 100, the index module 200, the buffer module 300, the coating and development module 400, and an interface module 600 may be sequentially disposed in a row in one direction. The purge module 700 may be provided in the interface module 600. Alternatively, the purge module 700 may be provided in various positions such as a position to which an exposure device 800 at a rear end of the interface module 600 is connected, or a side portion of the interface module 600. Hereinafter, a direction in which the load port 100, the index module 200, the buffer module 300, the coating and development module 400, and the interface module 600 are disposed may be referred to as a first direction Y, and a direction, perpendicular to the first direction Y, may be referred to as a second direction X, and a direction, perpendicular to each of the first and second directions Y and X, may be referred to as a third direction Z.

A substrate W may be moved in a state of being accommodated in a cassette 20. The cassette 20 may be sealed from the outside. As an example, a front open integrated pod (FOUP), having a door in front thereof, may be used as the cassette 20.

Hereinafter, the load port 100, the index module 200, the buffer module 300, the coating and development module 400, the interface module 600, and the purge module 700 will be described in detail.

The load port 100 may have a mounting table 120 on which the cassette 20 in which the substrate W is accommodated is disposed. A plurality of mounting tables 120 may be provided, and the mounting tables 120 may be disposed in a row in the second direction X. FIG. 1 illustrates an example in which four mounting tables 120 are provided, but the number thereof may be changed.

The index module 200 may transfer the substrate W, between the cassette 20, disposed on the mounting table 120 of the load port 100, and the buffer module 300. The index module 200 may include a frame 210, an index robot 220, and a guide rail 230.

The frame 210 may have a rectangular parallelepiped shape having an empty space therein, and may be disposed between the load port 100 and the buffer module 300. The frame 210 of the index module 200 may have a height, lower than that of a frame 310 of the buffer module 300.

The index robot 220 and the guide rail 230 may be disposed in the frame 210. The index robot 220 may be provided such that a hand 221, directly handling the substrate W, is movable and rotatable in the first direction Y, the second direction X, and the third direction Z. The index robot 220 may include the hand 221, an arm 222, a support 223, and a pedestal 224. The hand 221 may be fixedly installed on the arm 222. The arm 222 may have a stretchable structure and a rotatable structure. The support 223 may be disposed such that a length direction thereof is the same as the third direction Z. The arm 222 may be coupled to the support 223 so as to be movable along the support 223. The support 223 may be fixedly coupled to the pedestal 224. The guide rail 230 may be provided such that a length direction thereof is the same as the second direction X. The pedestal 224 may be coupled to the guide rail 230 to be linearly movable along the guide rail 230. In addition, although not illustrated, the frame 210 may further include a door opener, opening and closing a door of the cassette 20.

The buffer module 300 may include the frame 310, a first buffer 320, a second buffer 330, and a cooling chamber 340. The frame 310 may have a rectangular parallelepiped shape having an empty space therein, and may be disposed between the index module 200 and the coating and development module 400. The first buffer 320, the second buffer 330, and the cooling chamber 340 may be positioned in the frame 310. The cooling chamber 340, the second buffer 330, and the first buffer 320 may be sequentially disposed from the bottom in the third direction Z. The first buffer 320 may be positioned to have a height corresponding to that of a coating module 401 of the coating and development module 400, and the second buffer 330 and the cooling chamber 340 may be provided to have a height corresponding to that of a development module 402 of the coating and development module 400.

Each of the first buffer 320 and the second buffer 330 may temporarily store a plurality of substrates W. The first buffer 320 may include a housing 321 and a plurality of supports 322. In the first buffer 320, the supports 322 may be disposed in the housing 321, and may be spaced apart from each other in the third direction Z. The second buffer 330 may have a housing 331 and a plurality of supports 332. In the second buffer 330, the supports 332 may be disposed in the housing 331, and may be spaced apart from each other in the third direction Z. One substrate W may be disposed on each support 322 of the first buffer 320 and each support 332 of the second buffer 330. The housing 331 may have an opening in a direction in which the index robot 220 is provided, such that the index robot 220 may carry the substrate W into or out of the support 332 in the housing 331.

The first buffer 320 have a structure may substantially similar to that of the second buffer 330. However, the housing 321 of the first buffer 320 may have openings in a direction in which a first buffer robot 360 is provided and in a direction in which a coating portion robot 421, positioned in the coating module 401, is provided. The number of supports 322, provided in the first buffer 320, may be the same as or different from the number of supports 332, provided in the second buffer 330. According to an example, the number of supports 332, provided in the second buffer 330, may be greater than the number of supports 322 provided in the first buffer 320.

The cooling chamber 340 may cool the substrate W. The cooling chamber 340 may include a housing 341 and a cooling plate 342. The cooling plate 342 may have an upper surface on which the substrate W is disposed, and a cooling means 343 for cooling the substrate W. Various methods, such as cooling using coolant or cooling using a thermoelement, may be used as the cooling means 343. In addition, the cooling chamber 340 may include a lift pin assembly for positioning the substrate W on the cooling plate 342. The housing 341 may have openings in a direction in which the index robot 220 is provided and in a direction in which a development portion robot, provided in the development module 402, is provided, such that the index robot 220 and the development portion robot may carry the substrate W into or out of the cooling plate 342. In addition, doors for opening and closing the above-described openings may be provided in the cooling chamber 340. In addition, doors for opening and closing the above-described opening may be provided in the cooling chamber 340.

In the above-described example embodiments, the buffer module 300 has been described to include the cooling chamber 340, but the present disclosure is not limited thereto, and the cooling chamber 340 may be omitted, as necessary.

The coating module 401 may include a process of coating a photosensitive liquid such as a photoresist on the substrate W, and a heat treatment process, such as heating and cooling of the substrate W, before and after a resist coating process. The coating module 401 may have a coating chamber 410, a heat treatment chamber portion 500, and a conveyance chamber 420. For example, the coating chamber 410, the conveyance chamber 420, and the heat treatment chamber portion 500 may be sequentially disposed in the second direction X. That is, with respect to the conveyance chamber 420, the coating chamber 410 may be disposed on one side of the conveyance chamber 420, and the heat treatment chamber portion 500 may be disposed on the other side of the conveyance chamber 420.

A plurality of coating chambers 410 may be provided in the third direction Z. In addition, as illustrated in FIG. 1, a plurality of coating chambers 410 may be provided, or one coating member 410 may be provided in the first direction Y.

The heat treatment chamber portion 500 may include a baking chamber 510 and a cooling chamber 520, and a plurality of baking chambers 510 and a plurality of cooling chambers 520 may be provided in the third direction Z. The conveyance chamber 420 may be positioned in parallel to the first buffer 320 of the first buffer module 300 in a first direction 12. The coating portion robot 421 and the guide rail 422 may be positioned in the conveyance chamber 420. The conveyance chamber 420 may have a substantially rectangular shape. The coating portion robot 421 may transfer the substrate W, between the baking chamber 510, the cooling chamber 520, the coating chamber 410, and the first buffer 320 of the first buffer module 300.

The guide rail 422 may be disposed such that a length direction thereof is parallel to the first direction Y. The guide rail 422 may guide the coating portion robot 421 to linearly move in the first direction Y. The coating portion robot 421 may have a hand 423, an arm 424, a support 425, and a pedestal 426. The hand 423 may be fixedly installed on the arm 424. The arm 424 may have a stretchable structure, such that the hand 423 may move in a horizontal direction. The support 425 may be disposed such that a length direction thereof is the same as the third direction Z. The arm 424 may be coupled to the support 425 so as to be linearly movable in the third direction Z along the support 425. The support 425 may be fixedly coupled to the pedestal 426, and the pedestal 426 may be coupled to the guide rail 422 so as to be movable along the guide rail 422.

All of the coating chambers 410 may have the same structure. However, types of treatment liquids used in the coating chambers 410 may be different from each other. A treatment liquid for forming a photoresist film or an antireflection film may be used as the treatment liquids.

The coating chamber 410 may coat a treatment liquid on the substrate W. A treatment unit, including a treatment container 411, a support portion 412, and a nozzle portion 413, may be provided in the coating chamber 410.

As an example, one treatment unit may be disposed in each coating chamber 410 in the first direction Y, but the present disclosure is not limited thereto, and two or more treatment units may be disposed in one coating chamber 410. The treatment units may all have the same structure. However, types of treatment liquids used in the treatment units may be different from each other. The treatment container 411 of the coating chamber 410 may have a shape having an open upper portion. The support portion 412 may be disposed in the treatment container 411, and may support the substrate W. The support portion 412 may be rotatably provided. The nozzle portion 413 may supply a treatment liquid onto the substrate W disposed on the support portion 412. The treatment liquid may be coated on the substrate W in a spin-coating manner. In addition, the coating chamber 410 may further selectively include a nozzle (not illustrated) for supplying a cleaning liquid such as deionized water (DIW) to clean a surface of the substrate W on which a treatment liquid is coated, and a back rinse nozzle (not illustrated) for cleaning a lower surface of the substrate W.

In the baking chamber 510, when the substrate W is mounted by the coating portion robot 421, the substrate W may be heat-treated. In the baking chamber 510, a pre-bake process of removing organic matter or moisture from a surface of the substrate W by heating the substrate W to a predetermined temperature may be performed before a treatment liquid is coated, or a soft bake process may be performed after a treatment liquid coated on a wafer W, and a cooling process of cooling the substrate W may be performed after each heating process.

A heating plate 511 may be a support plate on which the substrate W supplied into the baker chamber 510 is supported. The heating plate 511 may include a heating means 511a.

The heating means 511a may heat the substrate W disposed in the baking chamber 510. In this case, the substrate W may be heated in a state in which the baking chamber 510 is sealed, and the heating means 511a may heat the entire region of the substrate W to a uniform temperature. Such a heat treatment process may stabilize a liquid film, formed by coating the treatment liquid to the substrate W, by blowing organic matter on the liquid film.

In addition, the baking chamber 510 may further include a cooling plate (not illustrated). The cooling plate may receive coolant from a cooling unit 910 to be described below to cool the substrate W, thereby preventing the substrate W from being heated to an excessively high temperature by the heat treatment process. After the heat treatment process is completed, the substrate W may be transported to the cooling chamber 520.

The cooling chamber 520 may perform a cooling process of cooling the substrate W before a treatment liquid is coated. The cooling chamber 520 may include a cooling plate 521. The cooling plate may include a cooling means in which various methods, such as cooling using coolant or cooling using a thermoelement, are used to cool the substrate W.

The interface module 600 may connect the coating and development module 400 to an external exposure device 800. The interface module 600 may include an interface frame 610, a first interface buffer 620, a second interface buffer 630, and a conveyance robot 640, and the conveyance robot 640 may convey a substrate, conveyed to the first and second interface buffers 620 and 630, to the exposure device 800 when the coating and development module 400 is terminated. The first and second interface buffers 620 may include a housing 621 and a support 622, and the conveyance robot 640 and the coating portion robot 421 may carry the substrate W into or out of the support 622.

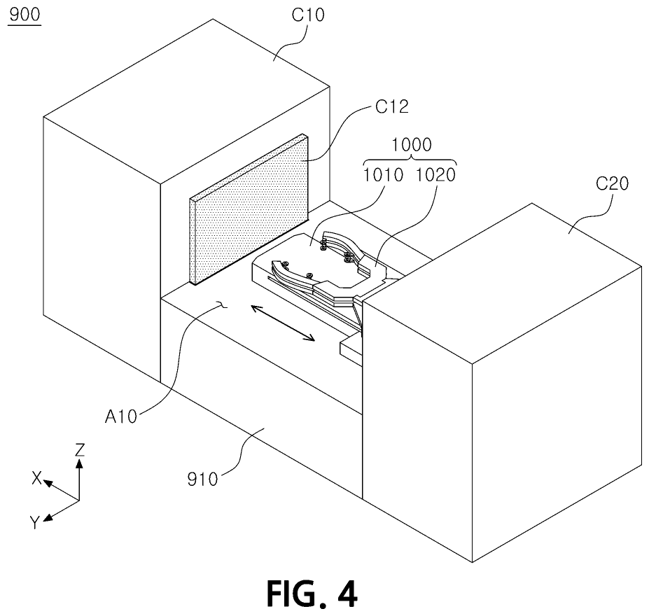

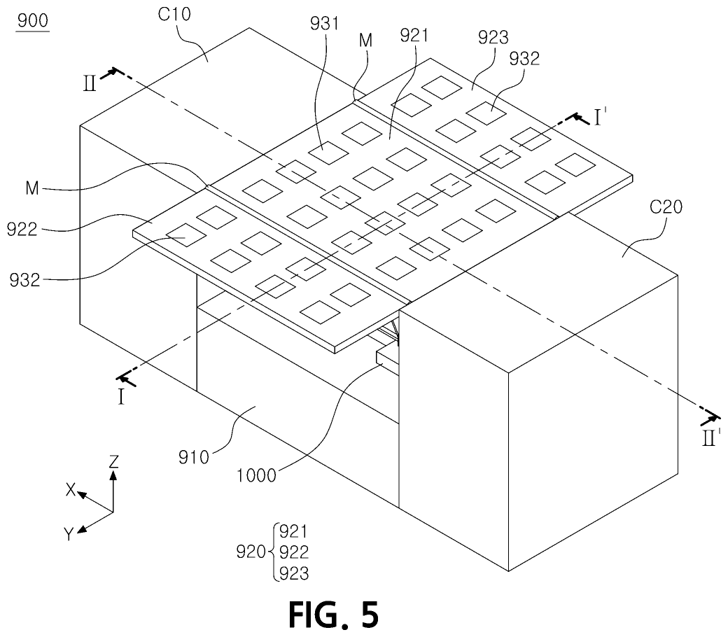

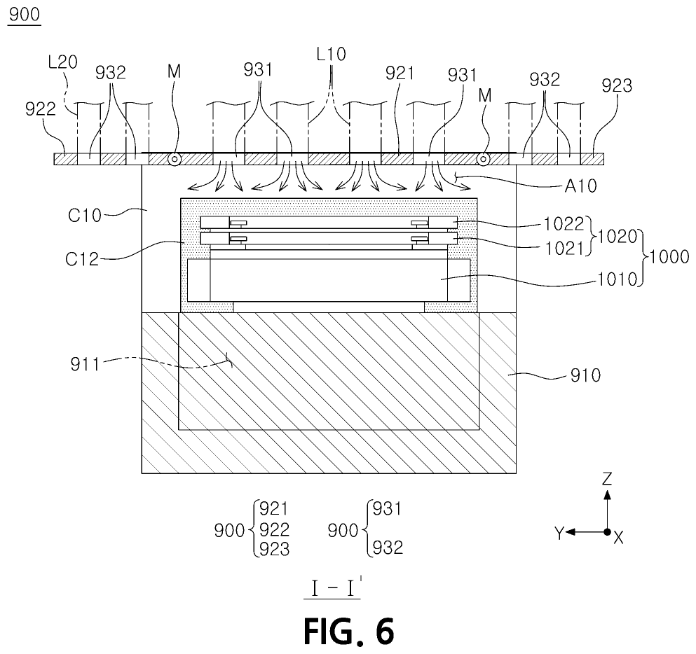

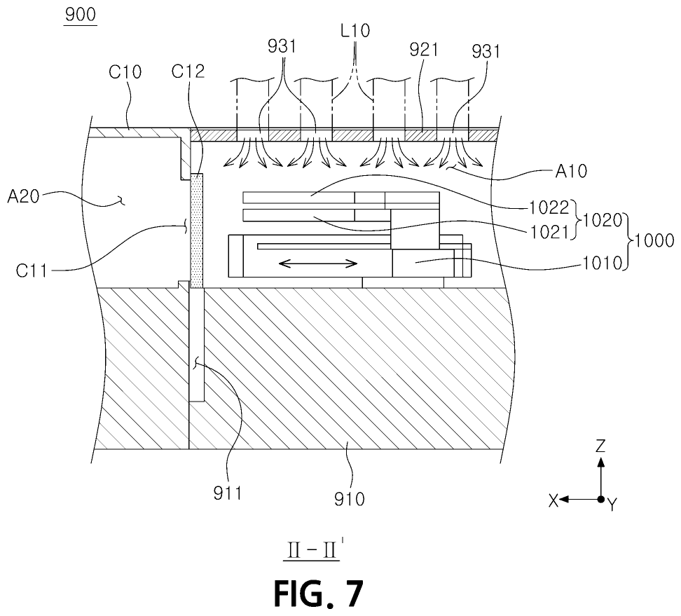

FIG. 4 is a schematic perspective view of a cover module excluding a cover portion according to an example embodiment of the present disclosure. FIG. 5 is a perspective view of an open state of a cover module according to an example embodiment of the present disclosure. FIG. 6 is a cross-sectional view of the cover module of FIG. 5 in a direction of I-I′. FIG. 7 is a cross-sectional view of a portion of the cover module of FIG. 5 in a direction of II-II′.

Referring to FIGS. 4 to 7, the substrate treatment apparatus 1 may further include a cover module 900 and a transport unit 1000.

The transport unit 1000 may transport the substrate W, between multiple processing chambers provided in the substrate treatment apparatus 1. In this case, the transport unit 1000 may include a transfer portion 1010 and a transport portion 1020.

The transfer portion 1010 may be disposed on a base portion 910 to be described below to be reciprocatable. More specifically, the transfer portion 1010 may be disposed to be reciprocatable in a length direction of the base portion 910. In this case, the length direction of the base portion 910 may be one of a direction, parallel to the first direction Y, a direction, parallel to the second direction X, or an oblique direction with respect to the first direction Y. However, for ease of description, a case in which the length direction of the base portion 910 is the direction, parallel to the second direction X, will be described.

The transport portion 1020 may grip the substrate W such that the transport unit 1020 may transport the substrate W. The transport portion 1020 may include a first robot arm 1021 and a second robot arm 1022 to carry the substrate W out of processing chambers C10 and C20, or to carry the substrate W into the processing chambers C10 and C20.

In addition, the transfer portion 1010 may rotate around a rotation shaft (not illustrated) extending in a direction, parallel to the third direction Z. Rotational driving of the transfer portion 1010 may be performed by driving force generated by a driver (not illustrated) connected to the rotation shaft. Rotational driving of the transfer portion 1010 may allow the transport unit 1020, disposed on the transfer portion 1010, to rotate in various directions.

The transport unit 1000 may be, for example, the above-described coating portion robot 421. As another example, the transport unit 1000 may be a device including a robot hand provided separately from the coating unit robot 421.

The cover module 900 may be disposed between the processing chambers C10 and C20, adjacent to each other. The cover module 900 may selectively close a space in which the transport unit 1000 is disposed, thereby preventing contact with moisture in the air while the substrate W is being transported. In this case, the cover module 900 may include a base portion 910, a cover portion 920, and a supply unit 930.

The above-described transport unit 1000 may be disposed on the base portion 910. In this case, the base portion 910 may connect some processing chambers, among multiple processing chambers included in the substrate treatment apparatus 1, to each other.

In an example embodiment, the base portion 910 may be disposed between a first processing chamber C10 and a second processing chamber C20, two processing chambers adjacent to each other. In this case, the base port 910 may connect one side surface of the first processing chamber C10 and one side surface of the second processing chamber C20 to each other. In this case, the one side surface of the first processing chamber C10 and the one side surface of the second processing chamber C20 may be disposed to oppose each other in the second direction X.

In the first processing chamber C10, some processes, among substrate treatment processes performed by the substrate treatment apparatus 1, may be performed. The first processing chamber C10 may be, for example, one of a bake chamber 510, a cooling chamber 520, and a coating chamber 410, but the present disclosure is not limited thereto. In this case, the first processing chamber C10 may include a first internal space A20, a first opening C11, and a first opening/closing portion C12.

In the first internal space A20, a heating device, a cooling device, or a coating device for performing a process of treating the substrate W may be disposed. The first internal space A20 may communicate with the outside by the first opening C11.

The first opening/closing portion C12 may be a door configured to open and close the first opening C11. For example, the first opening/closing portion C12 may reciprocate in the third direction Z to selectively open or close the first opening C11.

In the second processing chamber C20, a different type of treatment process from that of the first processing chamber C10 may be performed. In this case, the second processing chamber C20 may include a second internal space (not illustrated), a second opening (not illustrated) connected to the second internal space (not illustrated) to allow the second internal space to communicate with the outside, and a second opening/closing portion (not illustrated) to open and close the second opening (not illustrated), and specific features thereof may be the same as or similar to those of the first processing chamber C10.

As another example, at least one of the first processing chamber C10 and the second processing chamber C20 may be a chamber including a buffer module 301 for temporarily storing the substrate W before a substrate treatment process starts.

The base portion 910 may have a height, lower than those of the first processing chamber C10 and the second processing chamber C20. Accordingly, when the first processing chamber C10 and the second processing chamber C20 are connected to the base portion 910 interposed therebetween, the base portion 910 may have a shape similar to that of “C” in lateral view.

The base portion 910 may have an accommodation space 911. The accommodation space 911 may have a concave shape toward the inside of the base portion 910 from an upper surface of the base portion 910 in a downward direction-Z. The first opening/closing portion C12 of the first processing chamber C10 may be selectively inserted into the accommodation space 911. When the second opening/closing portion is provided in the second processing chamber C20, an accommodation space (not illustrated) into which the second opening/closing portion is selectively inserted may be further provided.

The cover portion 920 may cover a peripheral portion of the transport unit 1000, disposed on the base portion 910. The cover portion 920 may include an upper plate 921, a first cover 922, and a second cover 923. When the first cover 922 and the second cover 923 are closed, the cover portion 920 may form a transport space A10 surrounding an upper region of the base portion 910, together with the upper surface of the base portion 910.

The upper plate 921 may be disposed on an upper portion of the base portion 910. More specifically, the upper plate 921 may be disposed on an upper side of the first opening/closing portion C12. As an example, the upper plate 921 may be a plate having a cross-section, the same as or similar to that of the upper surface of the base portion 910. In this case, the upper plate 921 may have a length the same as that of the base portion 910. The upper plate 921 may have a width the same as that of the base portion 910, or may have a width narrower than that of the base portion 910.

The first cover 922 and the second cover 923 may be disposed at opposite side ends of the upper plate 921, respectively. In this case, the opposite side ends of the upper plate 921 may be opposite ends disposed in a width direction Y of the base portion 910. For ease of description, the opposite side ends of the upper plate 921 will be referred to as a first end and a second end, respectively. The upper plate 921 may be formed to have a width narrower than that of the base portion 910.

The first cover 922 may be disposed at the first end of the upper plate 921. The first cover 922 may open and close one side portion of the transport space A10. In this case, the one side portion of the transport space A10 may be opposite side portions of the transport space A10 formed to oppose each other in the width direction X, and the opposite side portions may be opened and closed by the first cover 922 and the second cover 923, respectively.

The first cover 922 may have a shape corresponding to that of the one side portion of the transport space A10. As an example, the one side portion of the transport space A10 may be a rectangular open region. In this case, the first cover 922 may be provided as a plate having a cross-sectional shape and a size the same as those of the one side portion of the transport space A10.

In an example embodiment, the first cover 922 may be connected to the first end of the upper plate 921 through a rotating member M. In this case, the first cover 922 may rotate in a first rotation direction R1 around a virtual first central axis (not illustrated), extending along a length direction X of the upper plate 921 and passing through the center of the rotating member M.

The rotating member M may use any rotatable method such as rotation by a hinge or the like. In addition, a driver (not illustrated) may be connected to the rotating member M to provide driving force for allowing the first cover 922 to rotate. The driver may use various methods including, for example, a hydraulic cylinder method, a rotating motor method or the like.

The second cover 923 may be disposed at the second end of the upper plate 921. The second cover 923 may open and close the other side portion of the transport space A10. In this case, the other side portion of the transport space A10 may be a side portion of the other one of the opposite side portions of the transport space A10, and may be disposed to oppose the one side portion, to which the first cover 922 is connected, in the width direction X.

The second cover 923 may have a shape corresponding to that of the other side portion of the transport space A10. For example, when the other side portion of the transport space A10 is a rectangular open region, the second cover 923 may be a plate having a cross-sectional shape and a size the same as those of the other side portion of the transport space A10 so as to correspond thereto.

In an example embodiment, the second cover 923 may be connected to the second end of the upper plate 921 through the rotating member M. In this case, the second cover 923 may rotate in a second rotation direction R2 around a virtual second central axis (not illustrated), extending in the length direction X of the upper plate 921 and passing through the center of the rotating member M. In this case, the second rotation direction R2 may be a direction, opposite to the first rotation direction R1 of the first cover 922.

The rotating member M may use any rotatable method such as rotation by a hinge or the like. In addition, a driver (not illustrated) may be connected to the rotating member M. The driver may be configured to provide driving force for allowing the first cover 922 to rotate, and various methods, such as a hydraulic cylinder method, a rotating motor method, or the like, may be used, for example, as described above.

The supply unit 930 may supply gas to the transport space A10. The supplied gas may be dry air or nitrogen gas having little moisture content. Hereinafter, for ease of description, a case in which gas is nitrogen gas will be mainly described. Nitrogen gas may be supplied by the supply unit 930, thereby preventing the substrate W transported by the transport unit 1000 from coming into contact with moisture in the transport space A10. In this case, the supply unit 930 may include a first supply portion 931 and a second supply portion 932.

The first supply portion 931 may be disposed on the upper plate 921 of the cover portion 920. As illustrated in FIGS. 6 and 7, a first supply line L10 may be connected to the first supply portion 931. The first supply line L10 may supply nitrogen gas supplied from a gas supply device (not illustrated) to the first supply portion 931. It is illustrated that the first supply portion 931 has a rectangular shape, but a shape and size of the first supply portion 931 may be changed.

A plurality of first supply portions 931 may be provided. The plurality of first supply portions 931 may be disposed on the upper plate 921 in a distributed manner. The first supply line L10 may be connected to each of the plurality of first supply portions 931. In this case, the first supply lines L10 may be connected to the gas supply device described above to receive nitrogen gas.

The plurality of first supply portions 931 may be arranged to have various shapes. For example, as illustrated in the drawings, the plurality of first supply portions 931 may be arranged on the upper plate 921 to have a lattice shape. As the first supply portions 931 is evenly disposed on the entire upper plate 921, nitrogen gas may be evenly supplied to all regions of the transport space A10.

The second supply portion 932 may be disposed on at least one of the first cover 922 and the second cover 923. As an example, the second supply portion 932 may be disposed on both the first cover 922 and the second cover 923. As another example, the second supply portion 932 may be disposed on only one of the first cover 922 and the second cover 923.

As illustrated in FIG. 6, a second supply line L20 may be connected to the second supply portion 932. The second supply line L20 may supply nitrogen gas supplied from a gas supply device (not illustrated) to the first supply portion 931. In this case, the second supply line L20 may be connected to a gas supply device the same as that of the first supply line L10, but may be connected to a gas supply device different from that of the first supply line L10. It is illustrated that the second supply portion 932 has a rectangular shape, but a shape and size of the second supply portion 932 may be changed.

A plurality of second supply portions 932 may be provided. The plurality of second supply portions 932 may be disposed on the first cover 922 and the second cover 923 in a distributed manner. The second supply line L20 may be connected to each of the plurality of second supply portions 932. In this case, the second supply lines L20 may be connected to the gas supply device described above to receive nitrogen gas.

The plurality of second supply portions 932 may be arranged to have various shapes. For example, as illustrated in the drawings, the plurality of second supply portions 932 may be arranged on each of the first cover 922 and the second cover 923 to have a lattice shape. As the second supply portion 932 is evenly disposed on the entire first cover 922 and second cover 923, nitrogen gas may be evenly supplied to the transport space A10 throughout the entire height of the transport space A10 in the third direction Z, when the covers 922 and 923 are closed.

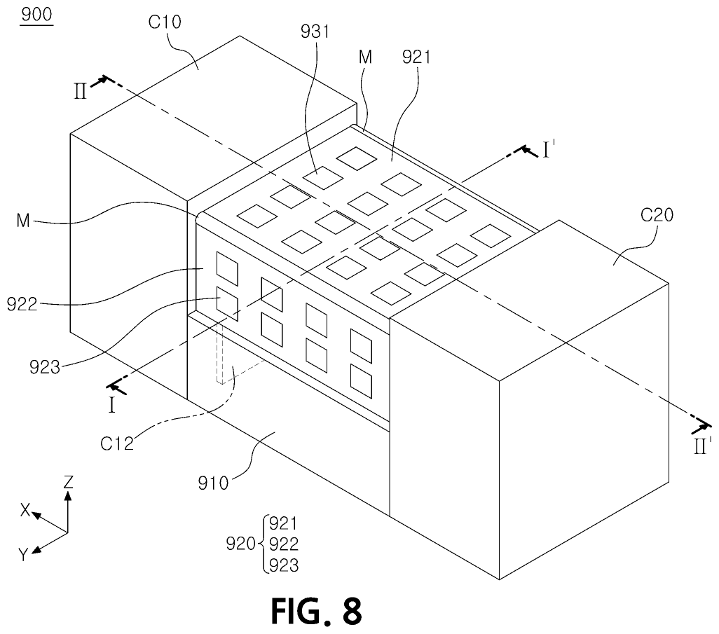

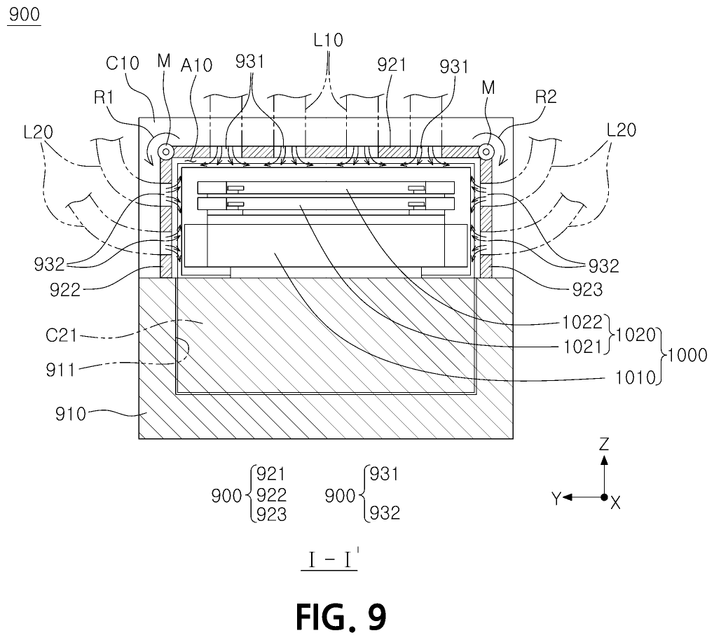

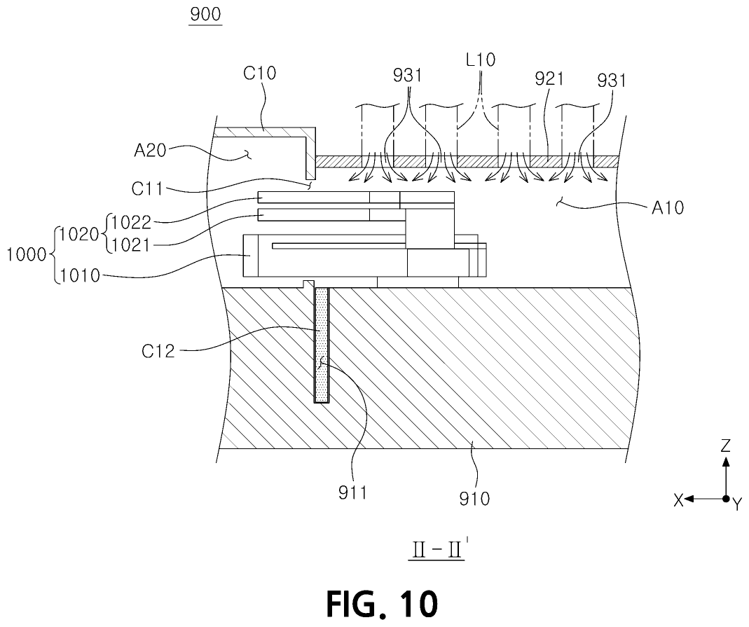

FIG. 8 is a perspective view of a closed state of the cover module according to example embodiment of the present disclosure. FIG. 9 is a cross-sectional view of the cover module of FIG. 8 in a direction of I-I′. FIG. 10 is a cross-sectional view of a portion of the cover module of FIG. 8 in a direction of II-II′.

Referring to FIGS. 8 to 10, when the transport unit 1000 transports the substrate W to the first processing chamber C10, a first opening C11 of the first processing chamber C10 may be opened by the first opening/closing portion C12. In this case, opening of the first opening C11 may be performed in a manner in which the first opening/closing portion C12 descends and is inserted into the accommodation space 911 of the base portion 910.

In addition, when the first opening/closing portion C12 starts to descend, the first cover 922 and the second cover 923 may respectively rotate in the first rotation direction R1 and the second rotation direction R2 to respectively close opposite side portions of the transport space A10. In this case, the first cover 922 may rotate in the first rotation direction R1 until an outer end of the first cover 922 comes into contact with an upper surface of the base portion 910. Thus, one side portion of the transport space A10 may be closed. In addition, the second cover 923 may rotate in the second rotation direction R2 until an outer end of the second cover 923 comes into contact with the upper surface of the base portion 910. Thus, the other side portion of the transport space A10 may be closed.

The base portion 910 may further include a sealing member (not illustrated). In this case, when the first cover 922 and the second cover 923 are closed, the sealing member may be disposed on each of portions of an upper surface of the base portion 920 meeting the outer end portion of the first cover 922 and the outer end portion of the second cover 923. Due to the sealing member, when the cover portion 920 closes the transport space A10, a space between the first cover 922 and the second cover 923 and the base portion 920 may be more firmly sealed.

In an example embodiment, the upper plate 921 may be configured to ascend and descends above the base portion 910. More specifically, the upper plate 921 may ascend and descends at a position higher than that of the first opening/closing portion C12 [or the first opening/closing portion C12 and the second opening/closing portion (not illustrated). In this case, when the first opening/closing portion C12 starts to descend as described above, the upper plate 921 of the cover portion 920 may also descend by a predetermined distance, and then the first cover 922 and the second cover 923 may be rotatably driven. A distance of the upper plate 921, descending, may be the same as or similar to a distance of the opening/closing portion (that is, the first opening/closing portion C12 and the second opening/closing portion (not illustrated), descending. In another example embodiment, a position of the upper plate 921 may be fixed. In this case, the upper plate 921 may be fixedly installed directly above the first opening/closing portion C12 (or the first opening/closing portion C12 and the second opening/closing portion (not illustrated). In this case, the cover portion 920 may be maintained in a fixed state in the third direction Z, and only the first cover 922 and the second cover 923 may be rotatably driven.

As described above, the opposite side portions of the transport space A10 may be covered by the first cover 922 and the second cover 923 disposed to oppose each other, such that the transport space A10 may be separated from the outside and closed, thereby preventing air and moisture, included in the air, from flowing into the transport space A10 from the outside of the transport space A10, except for gas supplied by the supply unit 930.

A process of opening or closing, by the cover module 900, the transport space A10 according to the above-described example embodiments of the present disclosure may be as follows.

First, when the transport unit 1000 disposed on the base portion 910 does not transport the substrate W, the opening/closing portions of the processing chambers C10 and C20 may be in a state in which openings thereof are closed. That is, the first opening portion C11 of the first processing chamber C10 may be closed by the first opening/closing portion C12, and the second opening portion (not illustrated) of the second processing chamber C20 may be closed by the second opening/closing portion (not illustrated). Accordingly, the first internal space C11 of the first processing chamber C10 and the second internal space (not illustrated) of the second processing chamber C20 may be separated from the transport space A10 without communicating with the transport space A10. In this case, the substrate W may be disposed in the second internal space of the second processing chamber C20, and the first internal space A20 of the first processing chamber C10 may be in a state in which the substrate W is not supplied.

Even before the transport of the substrate W starts as described above, the first supply portion 931 may supply nitrogen gas to the transport space A10. The supply of nitrogen gas by the first supply portion 931 may start, for example, immediately before the second opening/closing portion of the second processing chamber C20 is opened. As another example, the supply of nitrogen gas by the first supply portion 931 may start immediately after a process of treating the substrate W performed in the second processing chamber C20 is completed. As another example, the first supply portion 931 may continuously supply nitrogen gas while an overall substrate treatment process, performed by the substrate treatment apparatus 1, are being performed.

Subsequently, when a substrate treatment process is completed in the second processing chamber C20 in which the process of treating the substrate W is performed, or when the substrate W moves into the second processing chamber C20 including buffers 310 and 320, the second opening may be opened by the second opening/closing portion, descending. In this case, the first opening/closing portion C12 may be simultaneously opened or sequentially descend to open the first opening C11.

When the first opening/closing portion C12 or the second opening/closing portion starts to descend, the first cover 922 and the second cover 923 of the cover portion 920 may rotate to close the opposite side portions of the transport space A10. In this case, the first supply portion 931 may supply nitrogen gas as described above, and the second supply portion 932 may supply nitrogen gas into the transport space A10 after rotation operation of the first cover 922 and the second cover 923 is completed. In a state in which the transport space A10 is sealed by the cover portion 920, nitrogen gas may be supplied into the transport space A10 from an upper portion of the transport space A10 by the first supply portion 931, and from the opposite side portions of the transport space A10 by the second supply portion 932.

Subsequently, the transport unit 1000 may move to the second processing chamber C20 in the second direction X, grip the substrate W, and then rotate to move to the first processing chamber C10 in an opposite direction thereof. In this process, the transport unit 1000 may at least partially pass through the first opening C11 and transport the substrate W into the first internal space A20. While the transport unit 1000 is transporting the substrate W, the supply unit 930 may continuously supply nitrogen gas. Accordingly, while the substrate W is being transported between the processing chambers C10 and C20, the substrate W may not come into contact with moisture included in external air.

Subsequently, when the transport of the substrate W into the first processing chamber C10 is completed and the transport unit 1000 returns to an original position thereof, the first opening/closing portion C12 may ascend again in the third direction Z to close the first opening C11. When the first opening C11 is completely closed, the second supply portion 932 may stop supplying nitrogen gas. Thereafter, the first cover 922 and the second cover 923 may rotate again to return to original positions thereof parallel to the upper plate 921.

As described above, a plurality of cover modules 900 may be provided. The plurality of cover modules 900 may be disposed between processing chambers of the substrate treatment apparatus 1 and between a processing chamber and the buffer module 300, respectively, to prevent the substrate W from coming into contact with moisture while being transported.

The cover module 900 and the substrate treatment apparatus 1 including the according to example embodiments of the present disclosure, as described above, may supply nitrogen gas after closing a peripheral portion of the transport unit 1000 before the substrate W is introduced into the processing chambers C10 and C20, thereby creating a N₂ atmosphere. Accordingly, the substrate W may be transported in the N₂ atmosphere while moving between processing chambers C10 and C20, thereby preventing the substrate W from coming into contact with external gas and moisture included therein until the substrate W is supplied into the processing chamber C10. As a result, the occurrence of issues, such as damage to the substrate W due to contact with moisture and damage to a pattern due to particles included in external gas, may be prevented, thereby minimizing defects in the substrate W.

While example embodiments have been shown and described above, it will be apparent to those skilled in the art that modifications and variations could be made without departing from the scope of the present disclosure as defined by the appended claims.

What is claimed is:

1. A cover module comprising:
a base portion;
a cover portion disposed on an upper portion of the base portion, the cover portion including an upper plate, a first cover disposed at a first end of the upper plate to be openable and closable, and a second cover disposed at a second end of the upper plate to be openable and closable; and
a gas supply unit including a first supply portion disposed on the upper plate and a second supply portion disposed on at least one of the first cover and the second cover.

2. The cover module of claim 1, wherein the first cover and the second cover are disposed to oppose each other.

3. The cover module of claim 1, wherein the first cover is rotatably connected to the first end of the upper plate in a first rotation direction, and the second cover is rotatably connected to the second end of the upper plate in a second rotation direction.

4. The cover module of claim 3, wherein the first cover rotates in the first rotation direction such that an outer end of the first cover comes into contact with the base portion, and the second cover rotates in the second rotation direction such that an outer end of the second cover comes into contact with the base portion.

5. The cover module of claim 1, wherein the upper plate ascends and descends above the base portion.

6. The cover module of claim 1, wherein
a plurality of the first supply portions are provided, and
the plurality of first supply portions are disposed on the upper plate in a distributed manner.

7. The cover module of claim 1, wherein
a plurality of second supply portions are provided, and
the plurality of second supply portions are disposed on the first cover and the second cover in a distributed manner.

8. A substrate treatment apparatus comprising:
a first processing chamber having a first internal space, a first opening connected to the first internal space, and a first opening/closing portion opening and closing the first opening;
a cover module disposed on one side of the first processing chamber, the cover module including a base portion, a cover portion disposed on an upper portion of the base portion, the cover portion including an upper plate, a first cover disposed at a first end of the upper plate to be openable and closable, and a second cover disposed at a second end of the upper plate to be openable and closable, the second cover opposing the first cover in a first direction, and a gas supply unit including a first supply portion disposed on the upper plate and a second supply portion disposed on at least one of the first cover and the second cover.

9. The substrate treatment apparatus of claim 8, further comprising:
a transport unit disposed on the base portion to be reciprocatable in a second direction.

10. The substrate treatment apparatus of claim 9, wherein the cover portion closes the upper portion of the base portion to form a transport space, using the first cover and the second cover.

11. The substrate treatment apparatus of claim 10, wherein the first cover is rotatably connected to the first end of the upper plate in a first rotation direction, and the second cover is rotatably connected to the second end of the upper plate in a second rotation direction.

12. The substrate treatment apparatus of claim 11, wherein the first cover rotates in the first rotation direction to close one side surface of the transport space such that an outer end of the first cover comes into contact with the base portion, and the second cover rotates in the second rotation direction to close the other side surface of the transport space such that an outer end of the second cover comes into contact with the base portion.

13. The substrate treatment apparatus of claim 8, wherein the upper plate has a width narrower than that of the base portion.

14. The substrate treatment apparatus of claim 8, wherein the upper plate ascends and descends above the first opening/closing portion.

15. The substrate treatment apparatus of claim 8, wherein
a plurality of the first supply portions and a plurality of second supply portions are provided, and
the plurality of first supply portions are disposed on the upper plate in a distributed manner, and the plurality of second supply portions are disposed on the first cover and the second cover in a distributed manner.

16. The substrate treatment apparatus of claim 10, wherein the base portion has an accommodation space formed to be concave inwardly from an upper surface of the base portion.

17. The substrate treatment apparatus of claim 16, wherein the first opening/closing portion descends and is inserted into the accommodation space to allow the first internal space and the transport space to communicate with each other.

18. The substrate treatment apparatus of claim 17, wherein the first cover and the second cover rotate to close opposite side surfaces of the base portion, when the first opening/closing portion descends.

19. The substrate treatment apparatus of claim 11, wherein
the first supply portion supplies nitrogen gas into the transport space before the first cover and the second cover close opposite side surfaces of the transport space, and
the second supply portion supplies nitrogen gas into the transport space when the first cover and the second cover close the opposite side surfaces of the transport space.

20. A substrate treatment apparatus comprising:
a first processing chamber having a first internal space, a first opening connected to the first internal space, and a first opening/closing portion opening and closing the first opening;
a second processing chamber disposed to be spaced apart from one side of the first processing chamber;
a cover module between the first processing chamber and the second processing chamber, the cover module including a base portion having an accommodation space formed to be concave inwardly from an upper surface thereof, a cover portion disposed on an upper portion of the base portion, the cover portion including an upper plate, a first cover disposed at a first end of the upper plate to be rotatable in a first rotation direction, and a second cover disposed at a second end of the upper plate to be rotatable in a second rotation direction, the second cover opposing the first cover in a first direction, and a gas supply unit including a first supply portion disposed on the upper plate and a second supply portion disposed on at least one of the first cover and the second cover; and
a transport unit disposed on the base portion, the transport unit being reciprocatable in a length direction of the base portion, between the first processing chamber and second processing chamber,
wherein the cover portion closes the upper portion of the base portion to form a transport space using the first cover and the second cover, between the first processing chamber and the second processing chamber, and the first cover rotates to close one side surface of the transport space such that an outer end of the first cover comes into contact with the base portion, and the second cover rotates to close the other side surface of the transport space such that an outer end of the second cover comes into contact with the base portion,
the first opening/closing portion descends and is inserted into the accommodation space to allow the first internal space and the transport space to communicate with each other, and
the first cover and the second cover start to rotate to close opposite side surfaces of the base portion, when the first opening/closing portion descends.
